(19) United States
(12) Patent Application Publication
(10) Pub. No.: US 2023/0259681 A1
(43) Pub. Date: Aug. 17, 2023

(54) EQUIVALENT CIRCUIT MODEL, PROGRAM, RECORDING MEDIUM, AND SIMULATION DEVICE

(71) Applicant: Semiconductor Energy Laboratory Co., Ltd., Atsugi-shi, Kanagawa-ken (JP)

(72) Inventors: Hitoshi KUNITAKE, Isehara (JP); Haruyuki BABA, Isehara (JP)

(21) Appl. No.: 18/025,213

(22) PCT Filed: Sep. 9, 2021
(86) PCT No.: PCT/IB2021/058178

§ 371 Date: Mar. 8, 2023

(30) Foreign Application Priority Data
Sep. 22, 2020 (JP) 2020-158048

(51) Int. Cl. G06F 30/367; G06F 30/3323; G06F 30/3308

(52) U.S. Cl. CPC G06F 30/367; G06F 30/3323; G06F 30/3308

(57) ABSTRACT

A program for executing a simulation of a circuit including an anti-ferroelectric element is provided. An equivalent circuit model of an anti-ferroelectric element is set in the program. The equivalent circuit model includes, between a first terminal and a second terminal, a ferroelectric element, a linear resistor, a first transistor, and a second transistor. The first terminal is electrically connected to one of a pair of electrodes of the ferroelectric element and a first terminal of the linear resistor; the other of the pair of electrodes of the ferroelectric element is electrically connected to one of a source electrode and a drain electrode of the first transistor; a gate electrode of the first transistor is electrically connected to a gate electrode of the second transistor, one of a source electrode and a drain electrode of the second transistor, and a second terminal of the linear resistor; and the second terminal is electrically connected to the other of the source electrode and the drain electrode of the first transistor and the other of the source electrode and the drain electrode of the second transistor.

### TECHNICAL FIELD

One embodiment of the present invention relates to an equivalent circuit model, a program, a simulation device, and a recording medium.

Note that one embodiment of the present invention is not limited to the above technical field. The technical field of the invention disclosed in this specification and the like relates to an object, a method, or a manufacturing method. One embodiment of the present invention relates to a process, a machine, manufacture, or a composition of matter.

### BACKGROUND ART

Ferroelectric materials and their applications have been actively researched. According to Non-Patent Document 1, for example, research and development of a memory array using ferroelectrics have been conducted actively. In addition, the use of materials exhibiting an anti-ferroelectric property for a circuit such as DRAM (Dynamic Random Access Memory) is expected.

Circuit simulators are used in designing circuits including transistors. The circuit simulators have functions of verifying a variety of circuit operations by simulation. The simulation is performed using a device model that is made to approximate electrical characteristics of a transistor, a diode, a capacitor, a resistor, or the like. In order to improve simulation accuracy, the accuracy of the device model needs to be improved. In Non-Patent Document 2, a device model with a ferroelectric property is proposed. Note that in this specification and the like, a device model is sometimes referred to as a circuit model, an equivalent circuit, an equivalent circuit model, or the like.

### REFERENCE

### Non-Patent Document

[Non-Patent Document 1] T. S. Boescke, et al, “Ferroelectricity in hafnium oxide thin films”, Applied Physics Letters, 2011, vol 99, p. 102903
[Non-Patent Document 2] Y. Ishibashi, “Polarization Reversal Kinetics in Ferroelectric Liquid Crystals”, Japanese Journal of Applied Physics, 1985, vol. 24, Suppl. 24-2, pp. 126-129

### SUMMARY OF THE INVENTION

### Problems to be Solved by the Invention

As mentioned above, a device model with a ferroelectric property is proposed in Non-Patent Document 2. However, there is no known device model with an anti-ferroelectric property. Thus, it is difficult to run a simulation of a circuit including an anti-ferroelectric element.

In view of the above, an object of one embodiment of the present invention is to provide an equivalent circuit model of an anti-ferroelectric element. Another object of one embodiment of the present invention is to provide a program in which an equivalent circuit model of an anti-ferroelectric element is set. Another object of one embodiment of the present invention is to provide a recording medium in which the program is stored. Another object of one embodiment of the present invention is to provide a simulation device with the program.

Note that the description of these objects does not preclude the existence of other objects. One embodiment of the present invention does not have to achieve all of these objects. Other objects are apparent from and can be derived from the description of the specification, the drawings, the claims, and the like.

### Means for Solving the Problems

One embodiment of the present invention is an equivalent circuit model of an anti-ferroelectric element for simulation. One of a pair of electrodes of the anti-ferroelectric element is electrically connected to a first terminal, and the other of the pair of electrodes of the anti-ferroelectric element is electrically connected to a second terminal. The equivalent circuit model of the anti-ferroelectric element includes, between the first terminal and the second terminal, a ferroelectric element, a linear resistor, a first transistor, and a second transistor. The first terminal is electrically connected to one of a pair of electrodes of the ferroelectric element and a first terminal of the linear resistor; the other of the pair of electrodes of the ferroelectric element is electrically connected to one of a source electrode and a drain electrode of the first transistor; a gate electrode of the first transistor is electrically connected to a gate electrode of the second transistor, one of a source electrode and a drain electrode of the second transistor, and a second terminal of the linear resistor; and the second terminal is electrically connected to the other of the source electrode and the drain electrode of the first transistor and the other of the source electrode and the drain electrode of the second transistor.

Another embodiment of the present invention is a program to be executed by a computer, with an equivalent circuit model of an anti-ferroelectric element being set. One of a pair of electrodes of the anti-ferroelectric element is electrically connected to a first terminal, and the other of the pair of electrodes of the anti-ferroelectric element is electrically connected to a second terminal. The equivalent circuit model of the anti-ferroelectric element includes, between the first terminal and the second terminal, a ferroelectric element, a linear resistor, a first transistor, and a second transistor. The first terminal is electrically connected to one of a pair of electrodes of the ferroelectric element and a first terminal of the linear resistor; the other of the pair of electrodes of the ferroelectric element is electrically connected to one of a source electrode and a drain electrode of the first transistor; a gate electrode of the first transistor is electrically connected to a gate electrode of the second transistor, one of a source electrode and a drain electrode of the second transistor, and a second terminal of the linear resistor; and the second terminal is electrically connected to the other of the source electrode and the drain electrode of the first transistor and the other of the source electrode and the drain electrode of the second transistor.

Another embodiment of the present invention is a computer-readable recording medium in which the above program is stored.

Another embodiment of the present invention is a simulation device to perform simulation, with the above program being executed by the computer.

Another embodiment of the present invention is a method for generating an equivalent circuit model of an anti-ferroelectric element. The method for generating an equivalent circuit model of an anti-ferroelectric element includes a first step in which the equivalent circuit model of the anti-ferroelectric element is input, a second step in which an initial value of a parameter related to the equivalent circuit model of the anti-ferroelectric element is input, a third step in which actual measurement values of P-V characteristics or actual measurement values of I-V characteristics of the anti-ferroelectric element are input, and a fourth step in which the initial value of the parameter related to the equivalent circuit model of the anti-ferroelectric element is adjusted.

Another embodiment of the present invention is an equivalent circuit model of a ferroelectric element for simulation. One of a pair of electrodes of the ferroelectric element is electrically connected to a first terminal, and the other of the pair of electrodes of the ferroelectric element is electrically connected to a second terminal. The equivalent circuit model includes, between the first terminal and the second terminal, an anti-ferroelectric element and a linear resistor. The first terminal is electrically connected to one of a pair of electrodes of the anti-ferroelectric element and a first terminal of the linear resistor, and the second terminal is electrically connected to the other of the pair of electrodes of the anti-ferroelectric element and a second terminal of the linear resistor.

### Effect of the Invention

According to one embodiment of the present invention, an equivalent circuit model of an anti-ferroelectric element can be provided. According to another embodiment of the present invention, a program in which an equivalent circuit model of an anti-ferroelectric element is set can be provided. According to another embodiment of the present invention, a recording medium in which the program is stored can be provided. According to another embodiment of the present invention, a simulation device with the program can be provided.

Thus, a simulation of a circuit including an anti-ferroelectric element can be executed.

Note that the description of these effects does not preclude the existence of other effects. One embodiment of the present invention does not have to have all these effects. Other effects will be apparent from and can be derived from the description of the specification, the drawings, the claims, and the like.

### BRIEF DESCRIPTION OF THE DRAWINGS

FIG. 1A is a diagram showing P-V characteristics of a sample. FIG. 1B is a diagram showing I-V characteristics of the sample.

FIG. 2A is a diagram showing P-V characteristics of a sample. FIG. 2B is a diagram showing I-V characteristics of the sample.

FIG. 3A is a diagram showing a structure of an anti-ferroelectric element. FIG. 3B is a diagram of a circuit symbol of an anti-ferroelectric element. FIG. 3C and FIG. 3D are diagrams each showing an equivalent circuit model of an anti-ferroelectric element.

FIG. 4A is a diagram of a circuit symbol of a ferroelectric element. FIG. 4B is a diagram showing an equivalent circuit model of a ferroelectric element.

FIG. 5 is a flow chart of generation of an equivalent circuit model of an anti-ferroelectric element.

FIG. 6 is a block diagram showing a structure example of a simulation device.

### MODE FOR CARRYING OUT THE INVENTION

Embodiments will be described in detail with reference to the drawings. Note that the present invention is not limited to the following description, and it will be readily understood by those skilled in the art that modes and details of the present invention can be modified in various ways without departing from the spirit and scope of the present invention. Therefore, the present invention should not be construed as being limited to the description of embodiments below. Note that in structures of the present invention described below, the same reference numerals are used in common for the same portions or portions having similar functions in different drawings, and a repeated description thereof is omitted.

In addition, the position, size, range, and the like of each component illustrated in the drawings and the like do not represent the actual position, size, range, and the like in some cases for easy understanding of the invention. Therefore, the disclosed invention is not necessarily limited to the position, size, range, or the like disclosed in the drawings and the like. For example, in an actual manufacturing process, a resist mask or the like might be unintentionally reduced in size by treatment such as etching, which is not reflected in the drawings in some cases for easy understanding.

Furthermore, in a top view (also referred to as a plan view), a perspective view, or the like, the description of some components might be omitted for easy understanding of the drawings.

In addition, in this specification and the like, the term “electrode” or “wiring” does not functionally limit the components. For example, an “electrode” is used as part of a “wiring” in some cases, and vice versa. Furthermore, the term “electrode” or “wiring” also includes the case where a plurality of “electrodes” or “wirings” are formed in an integrated manner, for example.

Furthermore, in this specification and the like, a “terminal” in an electric circuit refers to a portion that inputs or outputs a current, inputs or outputs a voltage, and/or receives or transmits a signal. Accordingly, part of a wiring or an electrode functions as a terminal in some cases.

Note that the term “over” or “under” in this specification and the like does not necessarily mean directly over or directly under regarding the positional relationship between components, nor limit the positional relationship to direct contact. For example, the expression “an electrode B over an insulating layer A” does not require the electrode B to be provided on and in direct contact with the insulating layer A, nor excludes the case where another component is provided between the insulating layer A and the electrode B.

In addition, functions of a source and a drain are interchanged with each other depending on operation conditions and the like, for example, when a transistor of different polarity is employed or when the current direction is changed in a circuit operation; therefore, it is difficult to define which is the source or the drain. Thus, the terms “source” and “drain” can be interchangeably used in this specification.

Furthermore, in this specification and the like, the expression “electrically connected” includes the case where components are directly connected and the case where components are connected through an “object having any electric action.” Here, there is no particular limitation on the “object having any electric action” as long as electrical signals can be transmitted and received between components that are connected through the object. Thus, even when the expression “electrically connected” is used, there is a case where no physical connection portion is made and a wiring is just extended in an actual circuit.

Note that in this specification and the like, the terms “identical,” “same,” “equal,” “uniform,” and the like used in describing calculation values and measurement values contain an error of ±10% unless otherwise specified.

In addition, a voltage refers to a potential difference between a certain potential and a reference potential (e.g., a ground potential or a source potential) in many cases. Therefore, the terms “voltage” and “potential” can be replaced with each other in many cases. In this specification and the like, the terms “voltage” and “potential” can be replaced with each other unless otherwise specified.

Note that even a “semiconductor” has characteristics of an “insulator” when conductivity is sufficiently low, for example. Thus, a “semiconductor” can be replaced with an “insulator.” In that case, a “semiconductor” and an “insulator” cannot be strictly distinguished from each other because a boundary therebetween is not clear. Accordingly, a “semiconductor” and an “insulator” described in this specification can be replaced with each other in some cases.

Furthermore, a “semiconductor” has characteristics of a “conductor” when conductivity is sufficiently high, for example. Thus, a “semiconductor” can be replaced with a “conductor.” In that case, a “semiconductor” and a “conductor” cannot be strictly distinguished from each other because a boundary therebetween is not clear. Accordingly, a “semiconductor” and a “conductor” in this specification can be replaced with each other in some cases.

Note that ordinal numbers such as “first” and “second” in this specification and the like are used in order to avoid confusion among components and do not denote some kind of sequential order or priority, such as the order of steps or the stacking order. In addition, a term without an ordinal number in this specification and the like might be provided with an ordinal number in the scope of claims in order to avoid confusion among components. Furthermore, a term with an ordinal number in this specification and the like might be provided with a different ordinal number in the scope of claims. Moreover, even when a term is provided with an ordinal number in this specification and the like, the ordinal number might be omitted in the scope of claims and the like.

Note that in this specification and the like, an “on state” of a transistor refers to a state in which a source and a drain of the transistor are electrically short-circuited (also referred to as a “conduction state”). Furthermore, an “off state” of the transistor refers to a state in which the source and the drain of the transistor are electrically disconnected (also referred to as a “non-conduction state”).

In addition, in this specification and the like, an “on-state current” sometimes refers to a current that flows between a source and a drain when a transistor is in an on state. Furthermore, an “off-state current” sometimes refers to a current that flows between a source and a drain when a transistor is in an off state.

In addition, in this specification and the like, a high power supply potential VDD (hereinafter also simply referred to as “VDD” or an “H potential”) is a power supply potential higher than a low power supply potential VSS. Furthermore, the low power supply potential VSS (hereinafter also simply referred to as “VSS” or an “L potential”) is a power supply potential lower than the high power supply potential VDD. Moreover, a ground potential can also be used as VDD or VSS. For example, in the case where VDD is a ground potential, VSS is a potential lower than the ground potential, and in the case where VSS is a ground potential, VDD is a potential higher than the ground potential.

In addition, in this specification and the like, a gate refers to part or the whole of a gate electrode and a gate wiring. A gate wiring refers to a wiring for electrically connecting at least one gate electrode of a transistor to another electrode or another wiring.

Furthermore, in this specification and the like, a source refers to part or all of a source region, a source electrode, or a source wiring. A source region refers to a region with resistivity that is lower than or equal to a certain value in a semiconductor layer. A source electrode refers to part of a conductive layer that is connected to a source region. A source wiring refers to a wiring for electrically connecting at least one source electrode of a transistor to another electrode or another wiring.

Moreover, in this specification and the like, a drain refers to part or all of a drain region, a drain electrode, or a drain wiring. A drain region refers to a region with resistivity that is lower than or equal to a certain value in a semiconductor layer. A drain electrode refers to part of a conductive layer that is connected to a drain region. A drain wiring refers to a wiring for electrically connecting at least one drain electrode of a transistor to another electrode or another wiring.

### Embodiment 1

In this embodiment, an equivalent circuit model of an anti-ferroelectric element, and a program in which the equivalent circuit model of an anti-ferroelectric element is set, each of which is one embodiment of the present invention, will be described with reference to drawings.

In this specification and the like, an anti-ferroelectric element includes an anti-ferroelectric material, and a pair of conductors placed to sandwich the anti-ferroelectric material. Note that the pair of conductors may function as electrodes.

The equivalent circuit model of an anti-ferroelectric element can be expressed using a ferroelectric element and a linear resistor. To begin with, the fact that a sample of an anti-ferroelectric element can be expressed using a sample of a ferroelectric element and a sample of a linear resistor will be described.

First, the sample of a ferroelectric element is prepared. Note that the remnant polarization of the sample of a ferroelectric element is 12.4 μC/cm² (1.24×10⁻⁵ C/cm²). The sample of a ferroelectric element is hereinafter referred to as Sample 11.

When current following through Sample 11 is I_{fe}, the polarization P_{fe} of Sample 11 is calculated by Formula (1) below. In other words, the polarization P_{fe} of Sample 11 is calculated by time-integrating the current I_{fe} flowing through Sample 11.

$$\begin{matrix}[ Formula 1 ] & \\ {P}_{fe} = \frac{1}{{A}_{fe}} \int {I}_{fe} ( t ) dt & ( 1 )\end{matrix}$$

Here, A_{fe} is an electrode area of Sample 11.

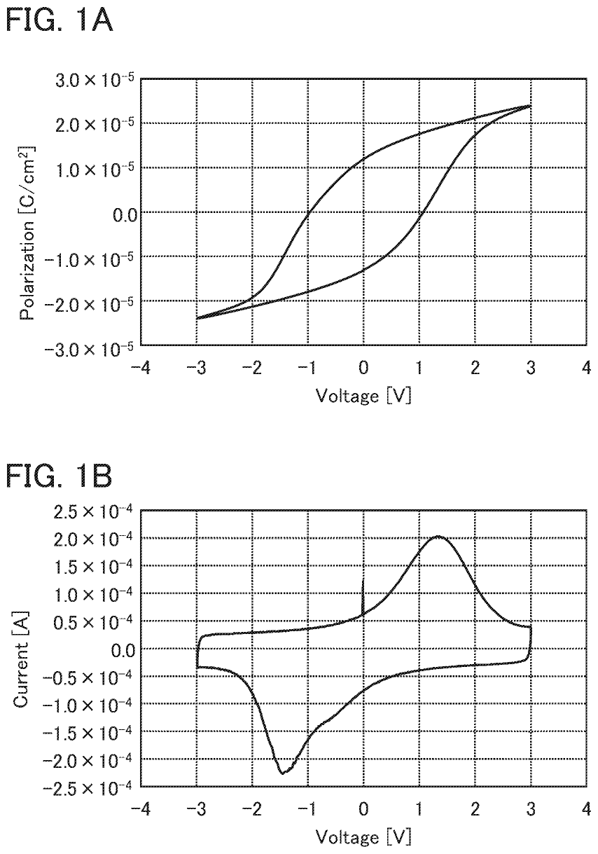

FIG. 1A shows assumed polarization (P)-voltage (V) characteristics of Sample 11. In FIG. 1A, the horizontal axis represents voltage [V] input to Sample 11, and the vertical axis represents polarization [C/cm²]. Note that the application of voltage to the ferroelectric element corresponds to the application of an external electric field. As shown in FIG. 1A, Sample 11 has hysteresis characteristics.

FIG. 1B shows assumed current (I)-voltage (V) characteristics of Sample 11. In FIG. 1B, the horizontal axis represents voltage [V] input to Sample 11, and the vertical axis represents current [A] output from Sample 11.

Next, the sample of the linear resistor is prepared. Note that the resistance value of the sample of the linear resistor is 38 kΩ. The sample of the linear resistor is hereinafter referred to as Sample 12.

It is assumed that the potential similar to the current I_{fe} flowing through Sample 11 is applied to Sample 12. Current flowing through Sample 12 at this time is Iᵣₑₛ.

Next, Sample 13 is prepared. Current flowing through Sample 13 is I_{afe}.

Here, the relation between the current I_{fe} flowing through Sample 11, the current Iᵣₑₛ flowing through Sample 12, and the current I_{afe} flowing through Sample 13 is defined by Formula (2) below.

[Formula 2]

I_{fe}−Iᵣₑₛ=I_{afe} (2)

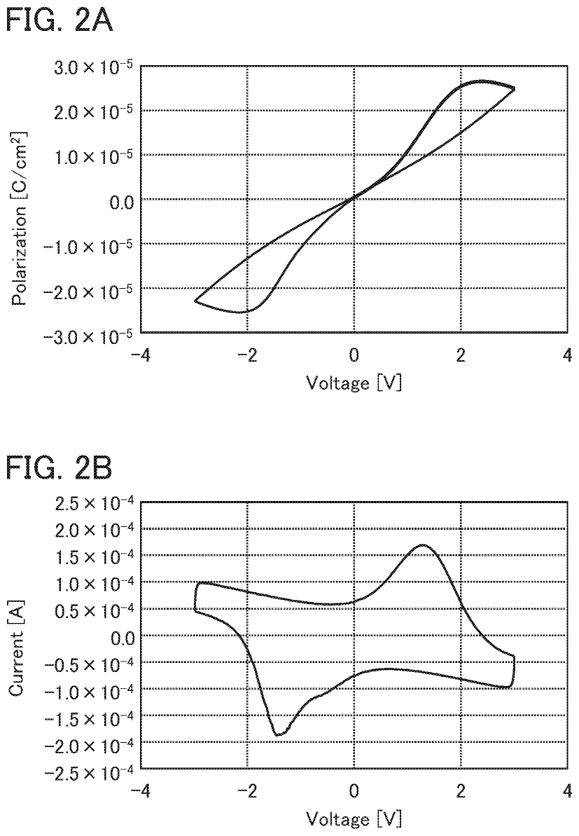

FIG. 2B shows I-V characteristics where the current Iᵣₑₛ flowing through Sample 12 is subtracted from the current I_{fe} flowing through Sample 11. Based on the definition of Formula (2), the waveform shown in FIG. 2B can also be referred to as I-V characteristics of Sample 13. In FIG. 2B, the horizontal axis represents voltage [V] input to Sample 13, and the vertical axis represents current [A] output from Sample 13.

The polarization P_{afe} of Sample 13 is calculated from Formula (3) below. In other words, the polarization P_{afe} of Sample 13 is calculated by time-integrating the current I_{afe} flowing through Sample 13.

$$\begin{matrix}[ Formula 3 ] & \\ {P}_{afe} = \frac{1}{{A}_{afe}} \int {I}_{afe} ( t ) dt & ( 3 )\end{matrix}$$

Here, A_{afe} is an electrode area of Sample 13.

FIG. 2A shows P-V characteristics of Sample 13 at this time. In FIG. 2A, the horizontal axis represents voltage [V] input to Sample 13, and the vertical axis represents polarization [C/cm²]. As shown in FIG. 2A, the polarization of Sample 13 increases as voltage gets higher, but becomes approximately 0 when voltage is 0 V. To put it another way, Sample 13 does not have remnant polarity but has hysteresis characteristics. That is, Sample 13 exhibits characteristics of an anti-ferroelectric element.

Thus, the waveform showing the characteristics of an anti-ferroelectric element can be obtained by subtracting the current component, which is derived from a linear resistor, from the waveform showing the characteristics of a ferroelectric element.

As described above, the equivalent circuit model of an anti-ferroelectric element can be expressed using a ferroelectric element and a linear resistor. In addition, the equivalent circuit model of a ferroelectric element can be expressed using an anti-ferroelectric element and a linear element.

### <Equivalent Circuit Model of Anti-Ferroelectric Element>

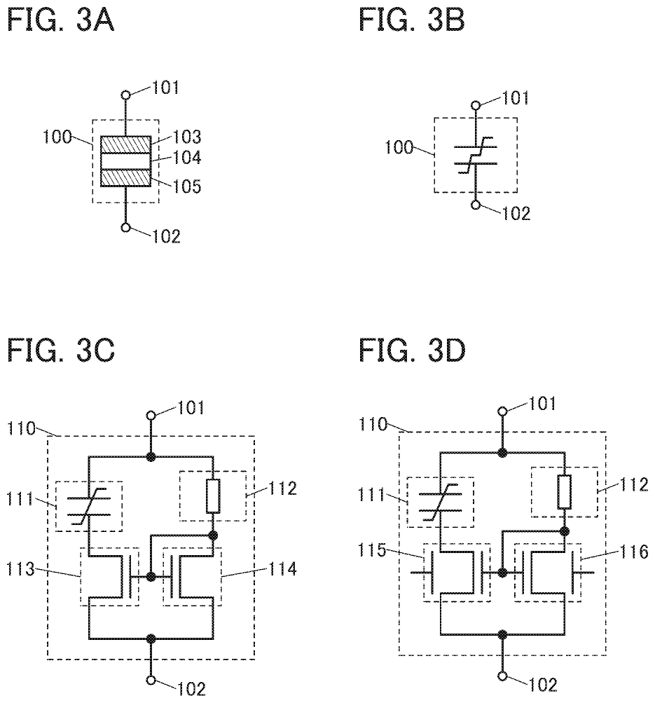

The equivalent circuit model of an anti-ferroelectric element can be expressed using a ferroelectric element and a linear resistor. Here, the equivalent circuit model of an anti-ferroelectric element will be described with reference to FIG. 3A to FIG. 3D.

FIG. 3A is a diagram showing a structure of an anti-ferroelectric element 100. The anti-ferroelectric element 100 has a structure in which a conductor 103, an anti-ferroelectric material 104, and a conductor 105 are stacked. The conductor 103 is electrically connected to a terminal 101, and the conductor 105 is electrically connected to a terminal 102. The anti-ferroelectric material 104 is positioned between the conductor 103 and the conductor 105. The conductor 103 and the conductor 105 function as a pair of electrodes of the anti-ferroelectric element 100. Note that the conductor 103 and the conductor 105 may be formed using the same material, or may be formed using different materials.

FIG. 3B is a diagram of a circuit symbol of the anti-ferroelectric element 100. One of the pair of electrodes of the anti-ferroelectric element 100 is electrically connected to the terminal 101, and the other of the pair of electrodes of the anti-ferroelectric element 100 is electrically connected to the terminal 102.

FIG. 3C is a diagram showing an equivalent circuit model 110 of the anti-ferroelectric element 100. As shown in FIG. 3C, the equivalent circuit model 110 of the anti-ferroelectric element 100 includes, between the terminal 101 and the terminal 102, a ferroelectric element 111, a linear resistor 112, a transistor 113, and a transistor 114. The terminal 101 is electrically connected to one of a pair of electrodes of the ferroelectric element 111 and a first terminal of the linear resistor 112. The other of the pair of electrodes of the ferroelectric element 111 is electrically connected to one of a source electrode and a drain electrode of the transistor 113. A gate electrode of the transistor 113 is electrically connected to a gate electrode of the transistor 114, one of a source electrode and a drain electrode of the transistor 114, and a second terminal of the linear resistor 112. The terminal 102 is electrically connected to the other of the source electrode and the drain electrode of the transistor 113 and the other of the source electrode and the drain electrode of the transistor 114.

Note that the equivalent circuit model 110 of the anti-ferroelectric element 100 is not limited to the structure shown in FIG. 3C. The equivalent circuit model 110 of the anti-ferroelectric element 100 may have a structure in which the transistor 113 and the transistor 114 in the equivalent circuit model 110 shown in FIG. 3C are respectively replaced with a transistor 115 with a back gate and a transistor 116 with a back gate, as illustrated in FIG. 3D. Alternatively, the equivalent circuit model 110 of the anti-ferroelectric element 100 may have a structure in which one of the two transistors included in the equivalent circuit model 110 is a single-gate transistor and the other is a transistor with a back gate.

### <Equivalent Circuit Model of Ferroelectric Element>

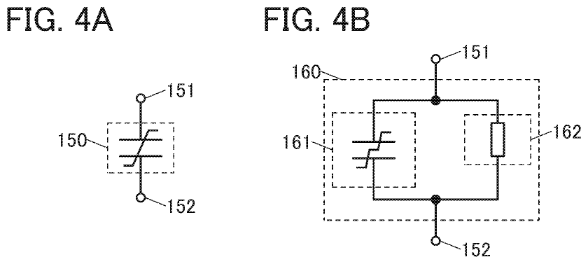

As described above, the equivalent circuit model of a ferroelectric element can be expressed using an anti-ferroelectric element and a linear resistor. Here, the equivalent circuit model of a ferroelectric element will be described with reference to FIG. 4A and FIG. 4B.

FIG. 4A is a diagram of a circuit symbol of a ferroelectric element 150. One of a pair of electrodes of the ferroelectric element 150 is electrically connected to a terminal 151, and the other of the pair of electrodes of the ferroelectric element 150 is electrically connected to a terminal 152.

FIG. 4B is a circuit diagram showing an equivalent circuit model 160 of the ferroelectric element 150. As shown in FIG. 4B, the equivalent circuit model 160 of the ferroelectric element 150 includes, between the terminal 151 and the terminal 152, an anti-ferroelectric element 161 and a linear resistor 162. The terminal 151 is electrically connected to one of a pair of electrodes of the anti-ferroelectric element 161 and a first terminal of the linear resistor 162. The terminal 152 is electrically connected to the other of the pair of electrodes of the anti-ferroelectric element 161 and a second terminal of the linear resistor 162.

### <Program>

Here, a program to be executed by a computer, which is one embodiment of the present invention, will be described.

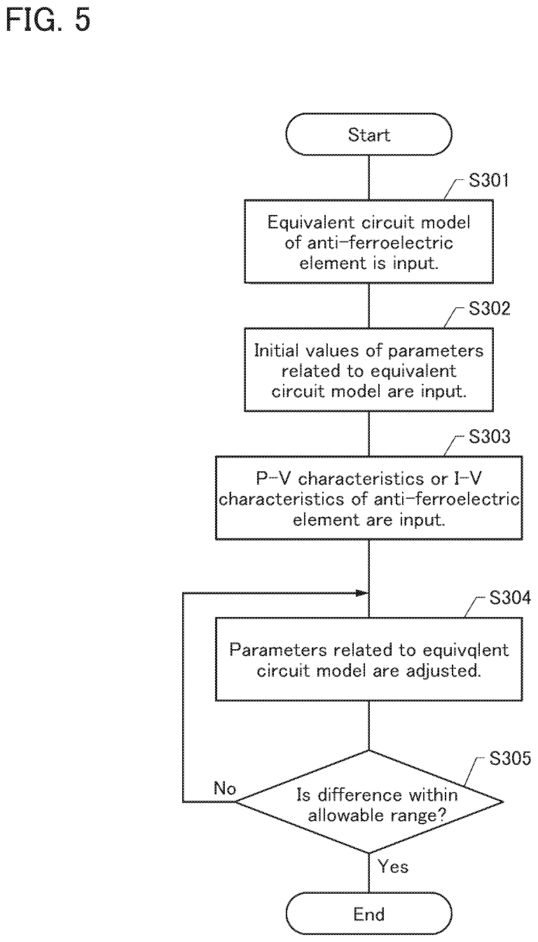

The above program has a function of generating an equivalent circuit model of an anti-ferroelectric element. FIG. 5 is a flow chart for generating an equivalent circuit model of an anti-ferroelectric element.

First, an equivalent circuit model of an anti-ferroelectric element is input by a user (Step S301).

Next, initial values of parameters related to the equivalent circuit model of the anti-ferroelectric element are input by the user (Step S302). Specifically, an initial value of a parameter related to a ferroelectric element, an initial value of a parameter related to a linear resistor, and an initial value of a parameter related to a transistor are input. Note that these initial values may be set in advance.

Next, actual measurement values of P-V characteristics or actual measurement values of I-V characteristics of the anti-ferroelectric element are input (Step S303). The user acquires the P-V characteristics or the I-V characteristics of the subject anti-ferroelectric element in advance.

Next, the parameters related to the equivalent circuit model of the anti-ferroelectric element are adjusted so as to become close to the actual measurement values of the P-V characteristics or the actual measurement values of the I-V characteristics of the anti-ferroelectric element, which are input in Step S303 (Step S304). Specifically, one or more of the parameter related to the ferroelectric element, the parameter related to the linear resistor, and the parameter related to the transistor are adjusted.

Next, whether or not the difference between the actual measurement values of the P-V characteristics or the actual measurement values of the I-V characteristics of the anti-ferroelectric element, which are input in Step S303 and the P-V characteristics or the I-V characteristics that are calculated from the equivalent circuit model of the anti-ferroelectric element is within an allowable range is determined (Step S305). In the case where the difference is out of the allowable range (No), the process returns to Step S304 and the parameters are adjusted again. In the case where the difference is within the allowable range (Yes), the process is terminated.

In the above manner, the equivalent circuit of the anti-ferroelectric element can be generated. Note that the program may have a function of optimizing the parameters related to the equivalent circuit model of the anti-ferroelectric element. This enables Step S304 and Step S305 to be performed automatically. To optimize the parameters, an optimization algorithm such as a steepest descent method may be used, or machine learning such as a neural network may be used.

When the equivalent circuit model of the anti-ferroelectric element generated through the above method is set to the program, the program can execute simulation of a circuit including the anti-ferroelectric element. Simulations of a circuit including an anti-ferroelectric element used as a capacitor, a circuit including DRAM with an anti-ferroelectric element, or the like can be executed, for example.

Note that the program for generating an equivalent circuit model of an anti-ferroelectric element may be different from a program for executing a simulation of a circuit including an anti-ferroelectric element, or may be incorporated in a program for executing a simulation of a circuit including an anti-ferroelectric element. Furthermore, it may have a structure in which the generated equivalent circuit model of an anti-ferroelectric element is stored in an auxiliary memory device or a database, and the equivalent circuit model of the anti-ferroelectric element stored in the auxiliary memory device or the database is accepted when the simulation of the circuit including an anti-ferroelectric element is executed.

The structure, method, and the like described in this embodiment can be used in an appropriate combination with the structures, the methods, and the like described in the other embodiment and the like.

### Embodiment 2

In this embodiment, a simulation device 200 of one embodiment of the present invention will be described.

### <Simulation Device>

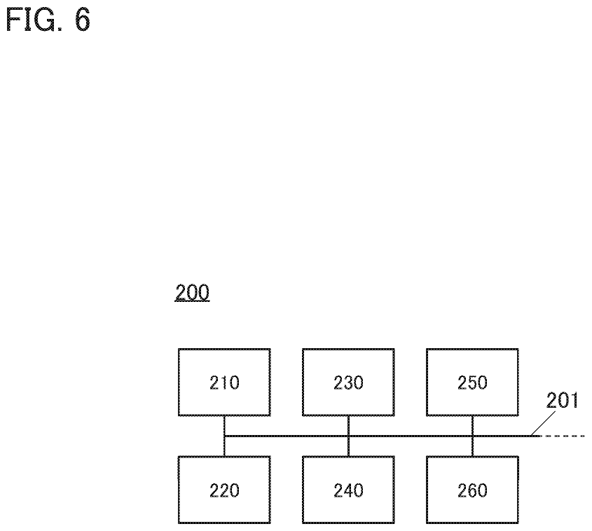

FIG. 6 is a block diagram illustrating a structure example of the simulation device 200. The simulation device 200 includes a control device 210, an arithmetic unit 220, a memory device 230, an auxiliary memory device 240, an input/output device 250, and a communication device 260. The devices are electrically connected to each other through a bus line 201.

### [Control Device 210 and Arithmetic Unit 220]

The control device 210 has a function of controlling operations of the other devices. The arithmetic unit 220 has a function of executing arithmetic processing for simulation. A central processing unit (CPU) or the like can be used as the arithmetic unit 220, for example.

The control device 210 and/or the arithmetic unit 220 may be achieved using a PLD (Programmable Logic Device) such as an FPGA (Field Programmable Gate Array) or an FPAA (Field Programmable Analog Array).

An arithmetic result obtained in the arithmetic unit 220 is output to the memory device 230 and/or the auxiliary memory device 240. In addition, the arithmetic result obtained in the arithmetic unit 220 is output to a display device (not illustrated), a printer, or the like through the input/output device 250 and/or the communication device 260.

### [Memory Device 230]

The memory device 230 has a function of storing programs and parameters for simulation operations, and at least part of the memory device 230 is preferably a rewritable memory. For example, the memory device 230 can include a volatile memory such as a RAM (Random Access Memory) or a nonvolatile memory such as a ROM (Read Only Memory).

As a RAM provided in the memory device 230, for example, a DRAM is used. A memory space is assigned to part of the RAM as a workspace of the simulation device 200. An operating system, an application program, data, and the like that are stored in the auxiliary memory device 240 are read into the RAM for execution.

In the case where a computer is made to function as the simulation device 200, for example, when a signal for starting a simulation program according to one embodiment of the present invention is input to the control device 210 through the input/output device 250 or the communication device 260, the control device 210 causes a simulation program stored in the auxiliary memory device 240 to be read into the memory device 230. When the simulation program is read into the memory device 230, the computer can function as the simulation device 200.

In addition, the control device 210 makes a variety of data, such as setting parameters input through the input/output device 250 or the communication device 260, be read into the memory device 230. The arithmetic unit 220 executes arithmetic processing by using the program, data, and the like read into the memory device 230. Note that the auxiliary memory device 240 can also be used as the memory device 230. Furthermore, a cache that is provided in the arithmetic unit 220 may be used as the memory device 230.

A BIOS (Basic Input/Output System), firmware, and the like for which rewriting is not needed can be stored in a ROM. As the ROM, a mask ROM, an OTPROM (One Time Programmable Read Only Memory), an EPROM (Erasable Programmable Read Only Memory), or the like can be used. Examples of the EPROM include a UV-EPROM (Ultra-Violet Erasable Programmable Read Only Memory) which can erase stored data by ultraviolet irradiation, an EEPROM (Electrically Erasable Programmable Read Only Memory), and a flash memory.

Part or all of the simulation program may be stored in the ROM.

### [Auxiliary Memory Device 240]

The auxiliary memory device 240 is a memory device that stores an operating system, an application program, data, and the like. In addition, a variety of parameters that are used in the arithmetic unit 220 are sometimes stored in the auxiliary memory device 240.

As the auxiliary memory device 240, a memory device employing a nonvolatile memory element, such as a flash memory, an MRAM (Magnetoresistive Random Access Memory), a PRAM (Phase change RAM), an ReRAM (Resistive RAM), or an FeRAM (Ferroelectric RAM); a memory device employing a volatile memory element, such as a DRAM (Dynamic RAM) or an SRAM (Static RAM); or the like may be used, for example. Furthermore, a memory media drive such as a hard disk drive (HDD) or a solid state drive (SSD) may be used, for example.

Alternatively, a memory device that can be detached through the input/output device 250, such as an HDD or an SSD, may be used as the auxiliary memory device 240, for example. Alternatively, a media drive for a recording medium such as a Blu-ray Disc (registered trademark) or a DVD can be used as the auxiliary memory device 240. Part or all of the simulation program may be stored in the recording medium.

Note that in the case where a memory device placed outside the simulation device 200 is used as the auxiliary memory device 240, a structure may be employed in which data is input and output to and from the simulation device 200 through wireless communication using the communication device 260.

### [Input/Output Device 250]

The input/output device 250 has a function of controlling input and output of signals between an external device and the simulation device 200. In addition, an HDMI (registered trademark) terminal, a USB terminal, a LAN (Local Area Network) connection terminal, or the like may be used as an external port of the input/output device 250. Furthermore, the input/output device 250 may have a transmitting/receiving function for optical communication using infrared rays, visible light, ultraviolet rays, or the like.

### [Communication Device 260]

The communication device 260 can perform communication via an antenna. For example, the communication device 260 controls a control signal for connecting the simulation device 200 to a computer network in response to instructions from the arithmetic unit 220, and transmits the signal to the computer network. Accordingly, communication can be performed by connection of the simulation device 200 to a computer network such as the Internet, which is the infrastructure of the World Wide Web (WWW), an intranet, an extranet, a PAN (Personal Area Network), a LAN (Local Area Network), a CAN (Campus Area Network), a MAN (Metropolitan Area Network), a WAN (Wide Area Network), or a GAN (Global Area Network). In the case where a plurality of communication methods are used, a plurality of antennas for the communication methods may be included.

The communication device 260 is provided with a high frequency circuit (RF circuit), for example, to transmit and receive RF signals. The high frequency circuit is a circuit for performing mutual conversion between an electromagnetic signal and an electric signal in a frequency band that is set by national laws to perform wireless communication with another communication apparatus using the electromagnetic signal. As a practical frequency band, several tens of kilohertz to several tens of gigahertz are generally used. A structure can be employed in which the high frequency circuit connected to an antenna includes a high frequency circuit portion compatible with a plurality of frequency bands and the high frequency circuit portion includes an amplifier, a mixer, a filter, a DSP (Digital Signal Processor), an RF transceiver, or the like. In the case of performing wireless communication, it is possible to use, as a communication protocol or a communication technology, a communication standard such as LTE (Long Term Evolution), GSM (Global System for Mobile Communication: registered trademark), EDGE (Enhanced Data Rates for GSM Evolution), CDMA 2000 (Code Division Multiple Access 2000), or WCDMA (Wideband Code Division Multiple Access: registered trademark), or a communication standard developed by IEEE such as Wi-Fi (registered trademark), Bluetooth (registered trademark), or ZigBee (registered trademark).

The simulation device 200 has the program described in the above embodiment. In addition to the above program, the simulation device 200 has a variety of programs that verify a variety of circuit operations. Furthermore, the simulation device 200 can use results obtained by execution of one verification program for another verification program.

The structure, method, and the like described in this embodiment can be used in an appropriate combination with the structures, the methods, and the like described in the other embodiment and the like.

### REFERENCE NUMERALS

11: sample, 12: sample, 13: sample, 100: anti-ferroelectric element, 101: terminal, 102: terminal, 103: conductor, 104: anti-ferroelectrics, 105: conductor, 110: equivalent circuit model, 111: ferroelectric element, 112: linear resistor, 113: transistor, 114: transistor, 115: transistor, 116: transistor, 150: ferroelectric element, 151: terminal, 152: terminal, 160: equivalent circuit model, 161: anti-ferroelectric element, 162: linear resistor, 200: simulation device, 201: bus line, 210: control device, 220: arithmetic unit, 230: memory device, 240: auxiliary memory device, 250: input/output device, 260: communication device

1. An equivalent circuit model of an anti-ferroelectric element,
wherein one of a pair of electrodes of the anti-ferroelectric element is electrically connected to a first terminal,
wherein the other of the pair of electrodes of the anti-ferroelectric element is electrically connected to a second terminal,
wherein the equivalent circuit model of the anti-ferroelectric element comprises between the first terminal and the second terminal:
a ferroelectric element;
a linear resistor;
a first transistor; and
a second transistor,
wherein the first terminal is electrically connected to one of a pair of electrodes of the ferroelectric element and a first terminal of the linear resistor,
wherein the other of the pair of electrodes of the ferroelectric element is electrically connected to one of a source electrode and a drain electrode of the first transistor,
wherein a gate electrode of the first transistor is electrically connected to a gate electrode of the second transistor, one of a source electrode and a drain electrode of the second transistor, and a second terminal of the linear resistor, and
wherein the second terminal is electrically connected to the other of the source electrode and the drain electrode of the first transistor and the other of the source electrode and the drain electrode of the second transistor.

2.-4. (canceled)

5. A computer-readable recording medium in which a program is stored,
wherein the program comprises an equivalent circuit model of an anti-ferroelectric element,
wherein the program is executed by a computer,
wherein one of a pair of electrodes of the anti-ferroelectric element is electrically connected to a first terminal,
wherein the other of the pair of electrodes of the anti-ferroelectric element is electrically connected to a second terminal,
wherein the equivalent circuit model of the anti-ferroelectric element comprises between the first terminal and the second terminal:
a ferroelectric element;
a linear resistor;
a first transistor; and
a second transistor,
wherein the first terminal is electrically connected to one of a pair of electrodes of the ferroelectric element and a first terminal of the linear resistor,
wherein the other of the pair of electrodes of the ferroelectric element is electrically connected to one of a source electrode and a drain electrode of the first transistor,
wherein a gate electrode of the first transistor is electrically connected to a gate electrode of the second transistor, one of a source electrode and a drain electrode of the second transistor, and a second terminal of the linear resistor, and
wherein the second terminal is electrically connected to the other of the source electrode and the drain electrode of the first transistor and the other of the source electrode and the drain electrode of the second transistor.

6. A simulation device to perform simulation, with a program,
wherein the program comprises an equivalent circuit model of an anti-ferroelectric element,
wherein the program is executed by a computer,
wherein one of a pair of electrodes of the anti-ferroelectric element is electrically connected to a first terminal,
wherein the other of the pair of electrodes of the anti-ferroelectric element is electrically connected to a second terminal,
wherein the equivalent circuit model of the anti-ferroelectric element comprises between the first terminal and the second terminal:
a ferroelectric element;
a linear resistor;
a first transistor; and
a second transistor,
wherein the first terminal is electrically connected to one of a pair of electrodes of the ferroelectric element and a first terminal of the linear resistor,
wherein the other of the pair of electrodes of the ferroelectric element is electrically connected to one of a source electrode and a drain electrode of the first transistor,
wherein a gate electrode of the first transistor is electrically connected to a gate electrode of the second transistor, one of a source electrode and a drain electrode of the second transistor, and a second terminal of the linear resistor, and
wherein the second terminal is electrically connected to the other of the source electrode and the drain electrode of the first transistor and the other of the source electrode and the drain electrode of the second transistor.
